(19) United States
(12) Patent Application Publication
(10) Pub. No.: US 2024/0305266 A1
(43) Pub. Date: Sep. 12, 2024

(54) RESONATOR AND RESONANCE DEVICE

(71) Applicant: Murata Manufacturing Co., Ltd., Nagaokakyo-shi (JP)

(72) Inventors: Yoshiyuki HIGUCHI, Nagaokakyo-shi (JP); Masakazu FUKUMITSU, Nagaokakyo-shi (JP)

(21) Appl. No.: 18/669,835

(22) Filed: May 21, 2024

Related U.S. Application Data
(63) Continuation of application No. PCT/JP2022/029124, filed on Jul. 28, 2022.

(30) Foreign Application Priority Data
Dec. 6, 2021 (JP) 2021-197531

(51) Int. Cl. H03H 9/17; H03H 9/15

(52) U.S. Cl. CPC H03H 9/171; H03H 2009/155

(57) ABSTRACT

A resonator that includes: a vibrating portion including a substrate, and a piezoelectric layer on the substrate; a holding portion around at least a part of the vibrating portion in a plan view of the substrate; and a support portion between the holding portion and the vibrating portion and that supports the vibrating portion. The vibrating portion includes a first portion and a second portion, a thickness of the second portion in a thickness direction of the substrate is larger than a thickness of the first portion in the thickness direction, and the vibrating portion has a recessed shape or a protruding shape defined by the first portion and the second portion on a side of the substrate opposite to the piezoelectric layer.

### CROSS REFERENCE TO RELATED APPLICATIONS

The present application is a continuation of International application No. PCT/JP2022/029124, filed Jul. 28, 2022, which claims priority to Japanese Patent Application No. 2021-197531, filed Dec. 6, 2021, the entire contents of each of which are incorporated herein by reference.

### TECHNICAL FIELD

The present description relates to a resonator and a resonance device.

### BACKGROUND ART

A resonance device is used for various applications such as a timing device, a sensor, and an oscillator in various electronic devices such as a mobile communication terminal, a communication base station, and a home appliance. As one of resonators provided in such a resonance device, for example, Patent Document 1 discloses a piezoelectric vibrator including a vibrating portion that performs contour vibration and a holding portion having a holding arm that holds the vibrating portion. In the configuration of Patent Document 1, the vibrating portion has a structure in which a silicon oxide film, a silicon layer, a lower electrode, a piezoelectric film, a first adjusting film, and a second adjusting film are laminated.

Patent Document 1: U.S. Pat. No. 10,333,486

### SUMMARY OF THE DESCRIPTION

However, in a resonator such as the piezoelectric vibrator of Patent Document 1 described above, there is a possibility that vibration leaks from the vibrating portion to the holding portion. Therefore, it is required to further improve a vibration confinement property (Q-value) by suppressing such vibration leakage.

The present description has been made in view of such circumstances, and an object of the present description is to provide a resonator and a resonance device capable of improving a vibration confinement property.

A resonator according to an aspect of the present description includes: a vibrating portion including a substrate, and a piezoelectric layer on a main surface of the substrate and which vibrates with a wide band along the main surface of the substrate in response to an applied voltage; a holding portion around at least a part of the vibrating portion in a plan view of the main surface of the substrate; and a support portion between the holding portion and the vibrating portion and that supports the vibrating portion, in which the vibrating portion includes a first portion in the plan view of the main surface of the substrate and a second portion in the plan view of the main surface of the substrate, a thickness of the second portion in a thickness direction intersecting the main surface of the substrate is larger than a thickness of the first portion in the thickness direction, and the vibrating portion has a recessed shape or a protruding shape defined by the first portion and the second portion on a side of the substrate opposite to the piezoelectric layer.

According to this aspect, by providing unevenness on the side in the substrate of the vibrating portion opposite to the piezoelectric layer, a vibration mode can be controlled, and unnecessary vibration such as bending vibration can be suppressed. Therefore, according to this aspect, it is possible to provide a resonator having a high vibration confinement property and a resonance device including the resonator.

According to the present description, it is possible to provide a resonator and a resonance device capable of improving a vibration confinement property.

### BRIEF DESCRIPTION OF THE DRAWINGS

FIG. 1 is an exploded perspective view schematically showing a configuration of a resonance device according to a first embodiment.

FIG. 2 is a cross-sectional view schematically showing a structure of a resonator according to the first embodiment.

FIG. 3 is a cross-sectional view schematically showing a structure of a resonator according to a second embodiment.

FIG. 4 is a cross-sectional view schematically showing a structure of a resonator according to a third embodiment.

FIG. 5 is a cross-sectional view schematically showing a structure of a resonator according to a fourth embodiment.

FIG. 6 is a cross-sectional view schematically showing a structure of a resonator according to a fifth embodiment.

FIG. 7 is a cross-sectional view schematically showing a structure of a resonator according to a sixth embodiment.

FIG. 8 is a plan view schematically showing a structure of a resonator according to a seventh embodiment.

FIG. 9A is a cross-sectional view of the resonator according to the seventh embodiment taken along IXA-IXA of FIG. 8.

FIG. 9B is a cross-sectional view of the resonator according to the seventh embodiment taken along line IXB-IXB of FIG. 8.

FIG. 9C is a cross-sectional view of the resonator according to the seventh embodiment taken along IXC-IXC line of FIG. 8.

FIG. 10 is a plan view schematically showing a structure of a resonator according to an eighth embodiment.

FIG. 11A is a cross-sectional view of the resonator according to the eighth embodiment taken along line XIA-XIA of FIG. 10.

FIG. 11B is a cross-sectional view taken along the line XIB-XIB of FIG. 10 of the resonator according to the eighth embodiment.

FIG. 11C is a cross-sectional view of the resonator according to the eighth embodiment taken along line XIC-XIC of FIG. 10.

FIG. 12 is a plan view schematically showing a structure of a resonator according to a ninth embodiment.

FIG. 13A is a cross-sectional view of the resonator according to the ninth embodiment taken along line XIIIA-XIIIA of FIG. 12.

FIG. 13B is a cross-sectional view of the resonator according to the ninth embodiment taken along line XIIIB-XIIIB of FIG. 12.

FIG. 13C is a cross-sectional view of the resonator according to the ninth embodiment taken along line XIIIC-XIIIC of FIG. 12.

FIG. 14 is a plan view schematically showing a structure of a resonator according to a tenth embodiment.

FIG. 15A is a cross-sectional view of the resonator according to the tenth embodiment taken along line XVA-XVA of FIG. 14.

FIG. 15B is a cross-sectional view of the resonator according to the tenth embodiment taken along line XVB-XVB of FIG. 14.

FIG. 15C is a cross-sectional view of the resonator according to the tenth embodiment taken along line XVC-XVC of FIG. 14.

FIG. 16 is a cross-sectional view schematically showing a structure of a resonator according to an eleventh embodiment.

### DESCRIPTION OF THE PREFERRED EMBODIMENTS

Hereinafter, embodiments of the present description will be described with reference to the accompanying drawings. The accompanying drawings of the present embodiment are for illustration, and the dimensions and shapes of the respective parts are schematic, and should not be construed as limiting the technical scope of the present description to the present embodiment.

### First Embodiment

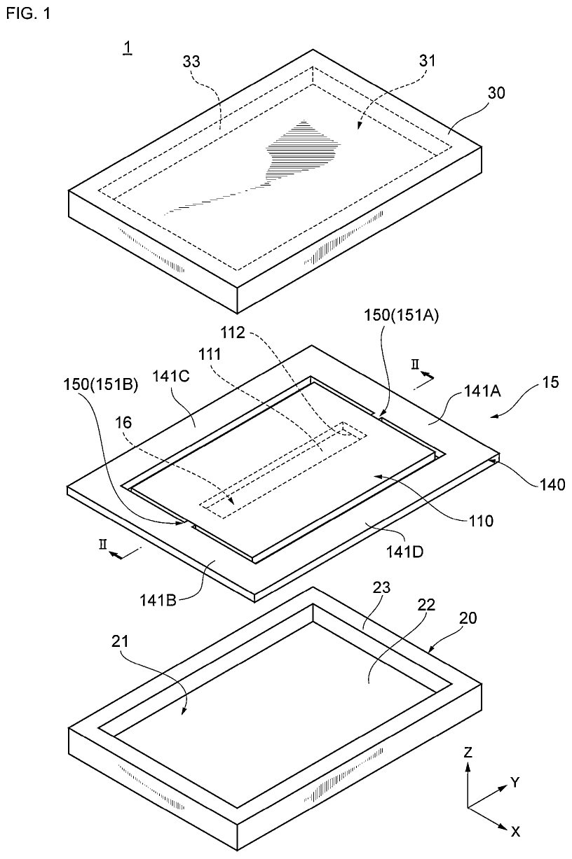

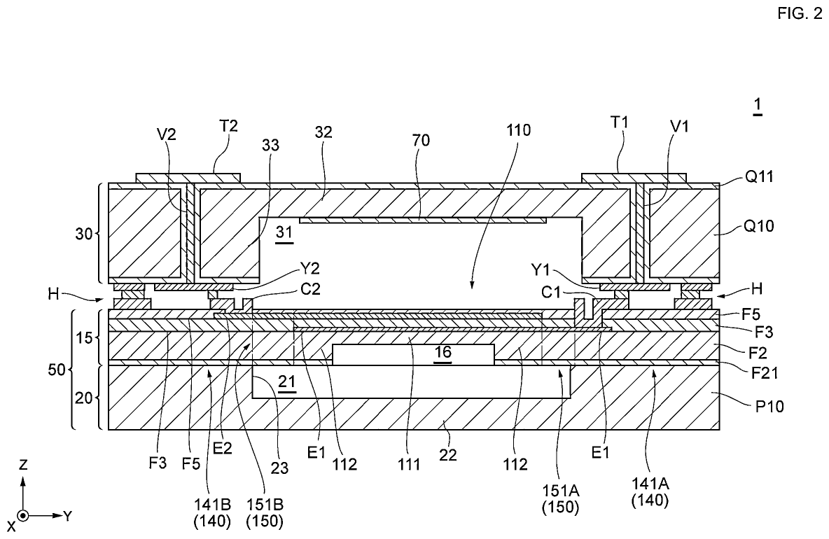

A configuration of a resonance device 1 according to a first embodiment of the present description will be described with reference to FIGS. 1 and 2. FIG. 1 is an exploded perspective view schematically showing a configuration of a resonance device according to the present embodiment. FIG. 2 is a cross-sectional view schematically showing a structure of a resonator according to the first embodiment.

Each of the drawings is accompanied by a Cartesian coordinate system consisting of an X-axis, a Y-axis, and a Z-axis for convenience in order to clarify the relationship between the drawings and to help understand the positional relationship between members. Directions parallel to the X-axis, the Y-axis, and the Z-axis are referred to as an X-axis direction, a Y-axis direction, and a Z-axis direction, respectively. In addition, for convenience, a Z-axis positive direction (a direction of an arrow on the Z-axis) is referred to as “up”, and a Z-axis negative direction (a direction opposite to the arrow on the Z-axis) is referred to as “down”.

A plane defined by the X-axis and the Y-axis is referred to as an XY plane, and the same applies to a YZ plane and a ZX plane.

First, an overall configuration of the resonance device 1 will be described with reference to FIG. 1. As shown in FIG. 1, the resonance device 1 includes a resonator 15, a lower cover 20, and an upper cover 30 disposed to face the lower cover 20 with the resonator 15 interposed therebetween. The lower cover 20, the resonator 15, and the upper cover 30 are laminated in this order in the Z-axis direction. The resonator 15 and the lower cover 20 are joined to each other to constitute a MEMS substrate 50. The upper cover 30 is joined to a resonator 15 side of the MEMS substrate 50. In other words, the upper cover 30 is joined to the lower cover 20 with the resonator 15 interposed therebetween. The lower cover 20 and the upper cover 30 correspond to a package structure having an internal vibration space for vibration of the vibrating portion 110, which will be described below.

The resonator 15 is a MEMS resonator manufactured by using MEMS technology. A frequency band of the resonator 15 is, for example, 1 kHz to 1 MHz. The resonator 15 is formed to be symmetrical with respect to, for example, the YZ plane that bisects the resonator 15 in the X-axis direction. The resonator 15 includes the vibrating portion 110, a holding portion 140, and a support portion 150.

The vibrating portion 110 vibrates in response to an applied alternating current voltage. The vibrating portion 110 is held to be vibratable in the vibration space provided between the lower cover 20 and the upper cover 30. The vibrating portion 110 extends along the XY plane in a non-vibration state (a state in which no voltage is applied), and vibrates in an expanding and contracting manner in the X-axis direction in a vibration state (a state in which a voltage is applied). That is, the vibrating portion 110 vibrates in a wide-band vibration mode.

In the example shown in FIG. 1, the vibrating portion 110 is provided in a plate shape having a main surface extending in the XY plane. A shape of the vibrating portion 110 when the XY plane is viewed in a plan view (hereinafter, simply referred to as a “plan view”) from the Z-axis positive direction is a rectangular shape having a pair of short sides extending in the X-axis direction and facing each other in the Y-axis direction, and a pair of long sides extending in the Y-axis direction and facing each other in the X-axis direction. It should be noted that the shape of the vibrating portion 110 is not limited to the above-described shape as long as the vibrating portion 110 is vibratable in the wide-band vibration mode.

The holding portion 140 forms the vibration space of the package structure together with the lower cover 20 and the upper cover 30. For example, the holding portion 140 is provided in a frame shape to surround the vibrating portion 110 when viewed in a plan view. The holding portion 140 includes a first frame portion 141A, a second frame portion 141B, a third frame portion 141C, and a fourth frame portion 141D. The first frame portion 141A extends in the X-axis direction on a Y-axis positive direction side of the vibrating portion 110. The second frame portion 141B extends in the X-axis direction on a Y-axis negative direction side of the vibrating portion 110. The third frame portion 141C extends in the Y-axis direction on an X-axis negative direction side of the vibrating portion 110. The fourth frame portion 141D extends in the Y-axis direction on an X-axis positive direction side of the vibrating portion 110. A Y-axis positive direction side end portion of the third frame portion 141C is connected to an X-axis negative direction side end portion of the first frame portion 141A, and a Y-axis positive direction side end portion of the fourth frame portion 141D is connected to an X-axis positive direction side end portion of the first frame portion 141A. A Y-axis negative direction side end portion of the third frame portion 141C is connected to an X-axis negative direction side end portion of the second frame portion 141B, and a Y-axis negative direction side end portion of the fourth frame portion 141D is connected to an X-axis positive direction side end portion of the second frame portion 141B.

The support portion 150 is provided between the vibrating portion 110 and the holding portion 140, and supports the vibrating portion 110. The support portion 150 includes a first support arm 151A and a second support arm 151B. The first support arm 151A and the second support arm 151B correspond to an example of a “pair of support arms” according to the present description. The first support arm 151A and the second support arm 151B each extend in the Y-axis direction. The first support arm 151A connects an X-axis direction center portion of a side surface of the vibrating portion 110 on the Y-axis positive direction side to an X-axis direction center portion of a side surface of the first frame portion 141A on the Y-axis negative direction side. The second support arm 151B connects an X-axis direction center portion of a side surface of the vibrating portion 110 on the Y-axis negative direction side and an X-axis direction center portion of a side surface of the second frame portion 141B on the Y-axis positive direction side.

The lower cover 20 has a rectangular flat plate-shaped bottom plate 22 having a main surface extending along the XY plane, and a side wall 23 extending from a peripheral edge portion of the bottom plate 22 toward the upper cover 30. The side wall 23 is joined to the holding portion 140 of the resonator 15. The lower cover 20 forms a cavity 21 surrounded by the bottom plate 22 and the side wall 23 on a side facing the vibrating portion 110 of the resonator 15. The cavity 21 is a rectangular parallelepiped-shaped cavity that opens upward.

The upper cover 30 has a rectangular flat plate-shaped bottom plate 32 having a main surface extending along the XY plane, and a side wall 33 extending from a peripheral edge portion of the bottom plate 32 toward the lower cover 20. The side wall 33 is joined to the holding portion 140 of the resonator 15. The upper cover 30 forms a cavity 31 surrounded by the bottom plate 32 and the side wall 33 on a side facing the vibrating portion 110 of the resonator 15. The cavity 31 is a rectangular parallelepiped-shaped cavity that opens downward. The cavity 21 and the cavity 31 face each other with the vibrating portion 110 of the resonator 15 interposed therebetween to form the vibration space of the package structure.

Next, a laminated structure of the resonance device 1 according to the first embodiment will be described with reference to FIG. 2. FIG. 2 is a cross-sectional view schematically showing the structure of the resonator according to the first embodiment. FIG. 2 is a cross-sectional view of the resonance device 1 taken along line II-II shown in FIG. 1.

The resonator 15 is held between the lower cover 20 and the upper cover 30. Specifically, the holding portion 140 of the resonator 15 is joined to each of the side wall 23 of the lower cover 20 and the side wall 33 of the upper cover 30. As described above, the vibration space in which the vibrating portion 110 is vibratable is formed by the lower cover 20, the upper cover 30, and the holding portion 140.

The resonator 15, the lower cover 20, and the upper cover 30 are each formed of, for example, a silicon (Si) substrate. The resonator 15, the lower cover 20, and the upper cover 30 may each be formed of a silicon on insulator (SOI) substrate in which a silicon layer and a silicon oxide film are laminated. In addition, the resonator 15, the lower cover 20, and the upper cover 30 may each be formed of a substrate other than the silicon substrate such as a compound semiconductor substrate, a glass substrate, a ceramic substrate, and a resin substrate as long as the substrate can be processed by a microfabrication technique.

A recess portion 16 is formed on a lower cover 20 side of the vibrating portion 110. The recess portion 16 is a rectangular parallelepiped-shaped cavity that opens downward. An upper cover 30 side of the vibrating portion 110 forms a substantially flat surface. The vibrating portion 110 includes a thin portion 111 corresponding to a bottom portion of the recess portion 16 and a thick portion 112 corresponding to a side wall portion of the recess portion 16. A thickness of the thick portion 112 in the Z-axis direction (hereinafter, simply referred to as “thickness”) is larger than a thickness of the thin portion 111. In the example shown in FIG. 2, the thickness of the thick portion 112 is substantially equal to a thickness of the support portion 150 and is also substantially equal to a thickness of the holding portion 140. The thin portion 111 corresponds to an example of a “first portion” according to the present description, and the thick portion 112 corresponds to an example of a “second portion” according to the present description.

A depth of the recess portion 16 corresponds to a difference between the thickness of the thick portion 112 and the thickness of the thin portion 111. The depth of the recess portion 16 is larger than a thickness of a silicon oxide film F21, which will be described later, and is smaller than a thickness of a silicon substrate F2, which will be described later. The depth of the recess portion 16 is, for example, larger than each of thicknesses of a metal film E1, the metal film E2, and a piezoelectric film F3, which will be described later, and is larger than a sum of these thicknesses.

When the resonator 15 is viewed in a plan view, the thin portion 111 is provided in a region (hereinafter, referred to as a “central region”) sandwiched between the first support arm 151A and the second support arm 151B in the Y-axis direction such that the Y-axis direction is a longitudinal direction of the thin portion 111. The central region between the first support arm 151A and the second support arm 151B is a region having a small displacement in a case where the vibrating portion 110 vibrates with a wide band. Therefore, it can be said that the thin portion 111 is provided in a region of the vibrating portion 110 where the displacement is small. A plane of the thin portion 111 when viewed in a plane (hereinafter, referred to as a “plane shape”) is, for example, a rectangular shape.

The thick portion 112 is provided in a region (hereinafter, referred to as an “outer end region”) with the central region interposed between both directions of the X-axis. The outer end region is a region having a large displacement in a case where the vibrating portion 110 vibrates with a wide band. In addition, the thick portion 112 is also provided between the thin portion 111 and the support portion 150. That is, the first support arm 151A and the second support arm 151B are connected to the thick portion 112 of the vibrating portion 110. When viewed in a plan view, the thick portion 112 is provided in a frame shape surrounding the thin portion 111. In addition, an area of the thick portion 112 is larger than an area of the thin portion 111.

The number, shapes, positions, and the like of thin portions are not limited to the above. A plurality of thin portions may be provided, and the thin portion may have a polygonal shape, a circular shape, an elliptical shape, or a planar shape obtained by a combination of these shapes.

The vibrating portion 110, the holding portion 140, and the support portion 150 included in the resonator 15 are integrally formed by the same process. The resonator 15 includes the silicon oxide film F21, the silicon substrate F2, the metal film E1, the piezoelectric film F3, the metal film E2, and a protective film F5. The resonator 15 is formed by patterning a multilayer body of the silicon oxide film F21, the silicon substrate F2, the metal film E1, the piezoelectric film F3, the metal film E2, the protective film F5, and the like through a removal process. The removal process is, for example, dry etching in which an argon (Ar) ion beam is irradiated. The recess portion 16 of the vibrating portion 110 is formed by a removal process such as dry etching, similar to the patterning described above. The formation of the recess portion 16 may be performed before the above-described patterning or after the above-described patterning.

The silicon oxide film F21 is provided on a part of a lower surface of the silicon substrate F2. Specifically, the silicon oxide film F21 is provided at lower surfaces of the thick portion 112 of the vibrating portion 110, the support portion 150, and the holding portion 140. The silicon oxide film F21 is sandwiched between a silicon substrate P10 and the silicon substrate F2. The silicon oxide film F21 is formed of silicon oxide containing, for example, SiO₂. The silicon oxide film F21 functions as a temperature characteristics correction film that reduces a temperature coefficient of a resonant frequency of the resonator 15, that is, a rate of change in the resonant frequency per unit temperature, at least in the vicinity of room temperature. Therefore, the silicon oxide film F21 improves temperature characteristics of the resonator 15. The silicon oxide film may also be formed on an upper surface of the silicon substrate F2. The silicon oxide film F21 corresponds to an example of a “temperature characteristics correction film” according to the present description.

The silicon substrate F2 is formed of, for example, a degenerated n-type silicon (Si) semiconductor having a thickness of about 6 μm. The silicon substrate F2 can contain phosphorus (P), arsenic (As), antimony (Sb), or the like as an n-type dopant. A resistance value of the degenerated silicon (Si) used in the silicon substrate F2 is, for example, less than 16 mΩ·cm, and is more desirably 1.2 mΩ·cm or less. The silicon semiconductor forming the silicon substrate F2 may be in any of a single crystal, a polycrystal, or an amorphous state. The silicon substrate F2 corresponds to an example of a “substrate” according to the present description.

The recess portion 16 is formed in the silicon substrate F2. The silicon substrate F2 forms a bottom surface of the recess portion 16, and the silicon oxide film F21 and the silicon substrate F2 form a side surface of the recess portion 16. Therefore, the thickness of the silicon substrate F2 in the thin portion 111 is smaller than the thickness of the silicon substrate F2 in the thick portion 112. That is, the vibrating portion 110 is configured to have a recessed shape on a side opposite to the piezoelectric film F3 in the silicon substrate F2 by the thin portion 111 and the thick portion 112.

The metal film E1 is laminated on the silicon substrate F2, the piezoelectric film F3 is laminated on the metal film E1, and the metal film E2 is laminated on the piezoelectric film F3. That is, the metal film E1, the metal film E2, and the piezoelectric film F3 are provided on a side opposite to a side on which the recess portion 16 of the silicon substrate F2 is formed. Each of the metal film E1 and the metal film E2 has a portion which functions as an excitation electrode that excites the vibrating portion 110 and a portion which functions as an extended electrode that electrically connects the excitation electrode to an external power supply. The portions of the metal film E1 and the metal film E2, which function as the excitation electrodes, face each other with the piezoelectric film F3 interposed therebetween in the vibrating portion 110. The portions of the metal film E1 and the metal film E2, which function as the extended electrodes, extend from the vibrating portion 110 to the holding portion 140 via the support portion 150, for example.

The piezoelectric film F3 corresponds to an example of a “piezoelectric layer” according to the present description. The metal film El corresponds to an example of a “lower electrode” according to the present description. The metal film E2 corresponds to an example of an “upper electrode” according to the present description.

Each of the thicknesses of the metal film E1 and the metal film E2 is, for example, about 0.1 μm to 0.2 μm. The metal film E1 and the metal film E2 are patterned into the excitation electrodes, the extended electrodes, and the like by a removal process such as etching after the film formation. The metal film E1 and the metal film E2 are formed of, for example, a metal material of which a crystal structure is a body-centered cubic structure. Specifically, the metal film E1 and the metal film E2 are formed of molybdenum (Mo), tungsten (W), or the like. In a case where the silicon substrate F2 is a degenerate semiconductor substrate having high conductivity, the metal film E1 may be omitted and the silicon substrate F2 may function as the lower electrode. From the viewpoint of suppressing the occurrence of parasitic capacitance, the occurrence of a short-circuit at the end portion of the resonance device 1, and the like, an insulating film may be provided between the metal film E1 and the silicon substrate F2. Such an insulating film may be formed of the same material as the silicon oxide film F21, or may be formed of the same material as the piezoelectric film F3.

The piezoelectric film F3 is a thin film formed of a piezoelectric body that converts electrical energy and mechanical energy into each other. The piezoelectric film F3 expands and contracts in the X-axis direction in an in-plane direction of the XY plane according to an electric field applied by the metal film E1 and the metal film E2. The vibrating portion 110 vibrates in an expanding and contracting manner in an in-plane direction due to the expansion and contraction of the piezoelectric film F3.

The piezoelectric film F3 is formed of a material having a crystal structure of a wurtzite-type hexagonal crystal structure, and primarily contains a nitride or an oxide such as aluminum nitride (AlN), scandium aluminum nitride (ScAlN), zinc oxide (ZnO), gallium nitride (GaN), and indium nitride (InN). Scandium aluminum nitride is aluminum nitride in which aluminum is partially substituted with scandium, and aluminum may also be substituted with two elements such as magnesium (Mg) and niobium (Nb) or magnesium (Mg) and zirconium (Zr) instead of scandium. The thickness of the piezoelectric film F3 is, for example, about 1 μm, but may also be about 0.2 μm to 2 μm.

The protective film F5 is laminated on the metal film E2. The protective film F5 protects, for example, the metal film E2 from oxidation. A material of the protective film F5 is, for example, an oxide, a nitride, or an oxynitride containing aluminum (Al), silicon (Si), or tantalum (Ta). A parasitic capacitance reduction film that reduces a parasitic capacitance formed between internal wires of the resonator 15 may be laminated on the protective film F5. The thickness of the protective film F5 is sufficiently larger than each of the thicknesses of the metal film E1, the metal film E2, and the piezoelectric film F3. Therefore, the protective film F5 mitigates the expression of unevenness caused by each of shapes of the metal film E1, the metal film E2, and the piezoelectric film F3 on an upper surface of the vibrating portion 110, and brings the upper surface of the vibrating portion 110 closer to a flat surface.

A frequency adjusting film that changes the frequency of the vibrating portion 110 according to a mass of the vibrating portion 110 changed by a removal process may be provided on the protective film F5. The frequency adjusting film is a metal material such as molybdenum (Mo), tungsten (W), gold (Au), platinum (Pt), nickel (Ni), or titanium (Ti).

An extended wire C1 and an extended wire C2 are formed on the protective film F5 of the holding portion 140. The extended wire C1 is electrically connected to the metal film E1 through through-holes formed in the piezoelectric film F3 and the protective film F5. The extended wire C2 is electrically connected to the metal film E2 through a through-hole formed in the protective film F5. The extended wire C1 and the extended wire C2 are formed of a metal material such as aluminum (Al), germanium (Ge), gold (Au), and tin (Sn).

The bottom plate 22 and the side wall 23 of the lower cover 20 are integrally formed of the silicon substrate P10. The silicon substrate P10 is formed of a non-degenerate silicon semiconductor, and a resistivity thereof is, for example, 10Ω·cm or more. A thickness of the lower cover 20 is larger than the thickness of the silicon substrate F2, and is, for example, about 150 μm.

In a case where the resonator 15 and the lower cover 20 are regarded as the MEMS substrate 50, for example, the silicon substrate P10 of the lower cover 20 corresponds to a support substrate (handle layer) of the SOI substrate, the silicon oxide film F21 of the resonator 15 corresponds to a buried oxide (BOX) layer of the SOI substrate, and the silicon substrate F2 of the resonator 15 corresponds to an active layer (device layer) of the SOI substrate.

The bottom plate 32 and the side wall 33 of the upper cover 30 are integrally formed of the silicon substrate Q10. A silicon oxide film Q11 is provided on a surface of the silicon substrate Q10. Specifically, the silicon oxide film Q11 is provided in a region between the silicon substrate Q10 and a through electrode V1 and a through electrode V2, which will be described later, in a region between the silicon substrate Q10 and an internal terminal Y1 and an internal terminal Y2, which will be described later, and in a region between the silicon substrate Q10 and an external terminal T1 and an external terminal T2, which will be described later. The silicon oxide film Q11 prevents short-circuiting of electrodes and the like through the silicon substrate Q10. Since an electrode or the like that may cause a short circuit is not provided on an inner wall of the cavity 31 in the surface of the silicon substrate Q10, the silicon substrate Q10 may be exposed on the inner wall of the cavity 31.

The silicon oxide film Q11 is formed, for example, by thermal oxidation of the silicon substrate Q10 or chemical vapor deposition (CVD). A thickness of the upper cover 30 is, for example, about 150 μm.

A metal film 70 is provided on a lower surface of the bottom plate 32 of the upper cover 30. The metal film 70 is a getter that absorbs gas in the vibration space formed by the cavities 21 and 31 to improve a degree of vacuum. The metal film 70 absorbs, for example, hydrogen gas. The metal film 70 contains, for example, titanium (Ti), zirconium (Zr), vanadium (V), niobium (Nb), tantalum (Ta), or an alloy containing at least one thereof. The metal film 70 may contain an alkali metal oxide or an alkaline earth metal oxide. For example, a layer (not shown) such as a layer that prevents diffusion of hydrogen from the silicon substrate Q10 to the metal film 70 or a layer that improves adhesion between the silicon substrate Q10 and the metal film 70 may be provided between the silicon substrate Q10 and the metal film 70.

The upper cover 30 is provided with the through electrode V1 and the through electrode V2. The through electrodes V1 and V2 are provided inside through-holes that pass through the side wall 33 in the Z-axis direction. The through electrodes V1 and V2 are surrounded by the silicon oxide film Q11 and are insulated from each other. The through electrodes V1 and V2 are formed by filling the through-holes with, for example, polycrystalline silicon (poly-Si), copper (Cu), or gold (Au).

The internal terminal Y1 and the internal terminal Y2 are provided on a lower surface of the upper cover 30, and the external terminal Tl and the external terminal T2 are provided on an upper surface of the upper cover 30. The internal terminal Y1 is connected to a lower end portion of the through electrode V1, and the external terminal T1 is connected to an upper end portion of the through electrode V1. The internal terminal Y2 is connected to a lower end portion of the through electrode V2, and the external terminal T2 is connected to an upper end portion of the through electrode V2. The internal terminal Y1 is a connection terminal that electrically connects the through electrode V1 to the extended wire C1, and the external terminal T1 is a mounting terminal that grounds the metal film E1. The internal terminal Y2 is a connection terminal that electrically connects the through electrode V2 to the extended wire C2, and the external terminal T2 is a mounting terminal that electrically connects the metal film E2 to an external power supply.

The internal terminals Y1 and Y2 are electrically insulated from each other by the silicon oxide film Q11. A plurality of external terminals including the external terminals T1 and T2 are also electrically insulated from each other by the silicon oxide film Q11. The internal terminal Y1 and Y2 and the external terminal T1 and T2 are formed by plating a metallization layer (base layer) such as chromium (Cr), tungsten (W), or nickel (Ni) with nickel (Ni), gold (Au), silver (Ag), copper (Cu), or the like.

A joint portion H is formed between the side wall 33 of the upper cover 30 and the holding portion 140 of the resonator 15. The joint portion H is provided in a frame shape that is continuous in a circumferential direction so as to surround the vibrating portion 110 when viewed in a plan view, and hermetically seals the vibration space formed by the cavities 21 and 31 in a vacuum state. The joint portion H is formed of, for example, a metal film in which an aluminum (Al) film, a germanium (Ge) film, and an aluminum (Al) film are laminated in this order from the resonator 15 side and eutectically joined. The joint portion H may contain gold (Au), tin (Sn), copper (Cu), titanium (Ti), aluminum (Al), germanium (Ge), titanium (Ti), silicon (Si), or an alloy containing at least one thereof. In addition, in order to improve the adhesion between the resonator 15 and the upper cover 30, the joint portion H may include an insulator made of a metal compound such as titanium nitride (TiN) or tantalum nitride (TaN). Although each metal film of the joint portion H is shown as an independent layer, in reality, a eutectic alloy is formed, so that a distinct boundary is not always present.

As described above, in the present embodiment, the vibrating portion 110 is configured to have a recessed shape on a side opposite to the piezoelectric film F3 that vibrates with a wide band in the silicon substrate F2. The vibrating portion 110 includes the thin portion 111 corresponding to the bottom portion of the recess portion 16 and the thick portion 112 corresponding to the side wall portion of the recess portion 16. The thickness of the thick portion 112 is larger than the thickness of the thin portion 111.

In a case where the wide-band vibration is adopted as a main vibration mode, bending vibration that bends in the Z-axis direction may also be generated due to asymmetry of the laminated structure in the Z-axis direction. The bending vibration causes the support portion 150 to vibrate and leak vibration energy to the holding portion 140, and may cause a decrease in a vibration confinement property.

Contrary to this, according to the configuration of the present embodiment, by providing the recess portion 16, the vibration mode can be controlled, and unnecessary vibration such as the bending vibration can be suppressed. Therefore, according to the present embodiment, it is possible to provide the resonator 15 having a high vibration confinement property and the resonance device 1 including the resonator 15. In addition, by providing the recess portion 16 on the lower cover 20 side of the vibrating portion 110 and making an upper cover 30 side surface, which is a side on which the excitation electrode or the like of the silicon substrate F2 in the vibrating portion 110 is provided, flatter than a lower cover 20 side surface, it is possible to suppress processing defects such as step coverage issues or short-circuiting of the excitation electrode.

In addition, since the area of the thin portion 111 is smaller than the area of the thick portion 112 when viewed in a plan view, a decrease in mechanical strength of the vibrating portion 110 due to the formation of the recess portion 16 is suppressed. Therefore, damage to the resonator 15 due to an impact during manufacturing and transportation can be suppressed, and reliability can be improved.

In addition, the silicon oxide film F21 is provided on the lower cover 20 side of the silicon substrate F2.

According to this aspect, an improvement in frequency-temperature characteristics can be achieved by correcting frequency-temperature characteristics of the silicon substrate F2 with the silicon oxide film F21.

In addition, the silicon oxide film F21 is provided at the thick portion 112 and is not provided at an inner wall of the recess portion 16.

According to this aspect, a manufacturing process of the resonator 15 can be simplified by forming the silicon oxide film F21 on one entire main surface of the silicon substrate F2 and then forming the thin portion 111 by removing parts of the silicon oxide film F21 and the silicon substrate F2. In addition, even in a case where the part of the silicon oxide film F21 is removed during the formation of the thin portion 111 as described above, since the area of the thin portion 111 is smaller than the area of the thick portion 112, an influence of the removal of the part of the silicon oxide film F21 on the frequency-temperature characteristics can be suppressed.

In addition, in the present embodiment, the silicon substrate F2 is adopted as the “substrate” according to the present description, and the silicon oxide film F21 is adopted as the “temperature characteristics correction film” according to the present description.

According to this aspect, since the silicon oxide film F21, which is easy to manufacture and inexpensive, is provided on the surface of the silicon substrate F2, which is widely used, the frequency-temperature characteristics can be easily and inexpensively corrected.

In addition, the thin portion 111 is provided in the central region sandwiched between the first support arm 151A and the second support arm 151B.

According to this aspect, by forming the thin portion 111 in the central region where the displacement during the vibration is small and the influence on the frequency-temperature characteristics is small, it is possible to achieve both favorable frequency-temperature characteristics and the high vibration confinement property.

Hereinafter, other embodiments will be described. The same or similar configurations as those shown in the first embodiment are designated by the same or similar reference numerals, and the description thereof will be omitted as appropriate. In addition, the same operation and effect as those of the same configuration will not be repeatedly described.

### Second Embodiment

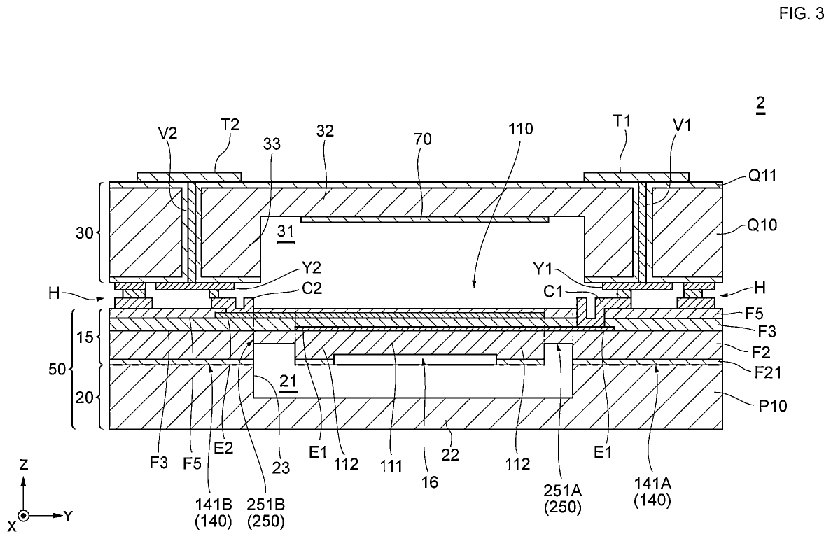

Next, a structure of a resonance device 2 according to a second embodiment will be described with reference to FIG. 3. FIG. 3 is a cross-sectional view schematically showing a structure of a resonator according to the second embodiment.

The present embodiment differs from the first embodiment in that thicknesses of a first support arm 251A and a second support arm 251B of a support portion 250 are smaller. Specifically, the thickness of the first support arm 251A is smaller than the thickness of the thick portion 112.

As shown in FIG. 3, the thickness of the first support arm 251A is smaller than the thickness of the thin portion 111. In addition, the thickness of the first support arm 251A is smaller than the thickness of the holding portion 140. The same applies to the second support arm 251B in terms of such a thickness relationship. However, the thickness of the first support arm 251A may be larger than the thickness of the thin portion 111, or may be the same as or larger than the thickness of the holding portion 140 as long as the thickness of the first support arm 251A is smaller than the thickness of the thick portion 112. The thickness of the first support arm 251A is, for example, substantially equal to the thickness of the second support arm 251B, but may also be larger than or smaller than the thickness of the second support arm 251B. In addition, in the example of FIG. 3, the silicon oxide film F21 is not provided on a surface of the support portion 250 on the lower cover 20 side, and the silicon substrate F2 is exposed. However, a silicon oxide film may also be provided on the surface of the support portion 250 on the lower cover 20 side.

The support portion 250 can be formed, for example, by etching from the lower cover 20 side. By making the thickness of the support portion 250 smaller than the thickness of the thick portion 112 to which the support portion 250 is connected as described above, it is possible to suppress the leakage of vibration from the vibrating portion 110 to the holding portion 140 via the support portion 250.

### Third Embodiment

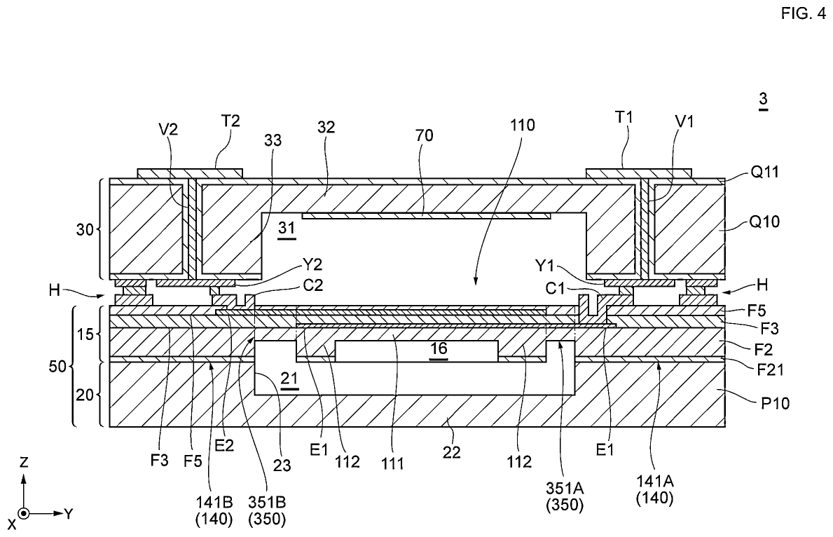

Next, a structure of a resonance device 3 according to a third embodiment will be described with reference to FIG. 4. FIG. 4 is a cross-sectional view schematically showing a structure of a resonator according to the third embodiment.

In the present embodiment, thicknesses of a first support arm 351A and a second support arm 351B of a support portion 350 are substantially the same as the thickness of the thin portion 111. The silicon oxide film F21 is not provided on a surface of the support portion 350 on the lower cover 20 side, and the silicon substrate F2 is exposed, similarly to the surface of the thin portion 111 on the lower cover 20 side. Accordingly, in a manufacturing process of the resonance device 3, etching processes of the support portion 350 and the thin portion 111 can be performed at one time, so that the manufacturing process can be simplified. In a case where the thickness of the support portion 350 and the thickness of the thin portion 111 are equal to each other, the silicon oxide film F21 may be provided on the surfaces of the support portion 350 and the thin portion 111 on the lower cover 20 side.

### Fourth Embodiment

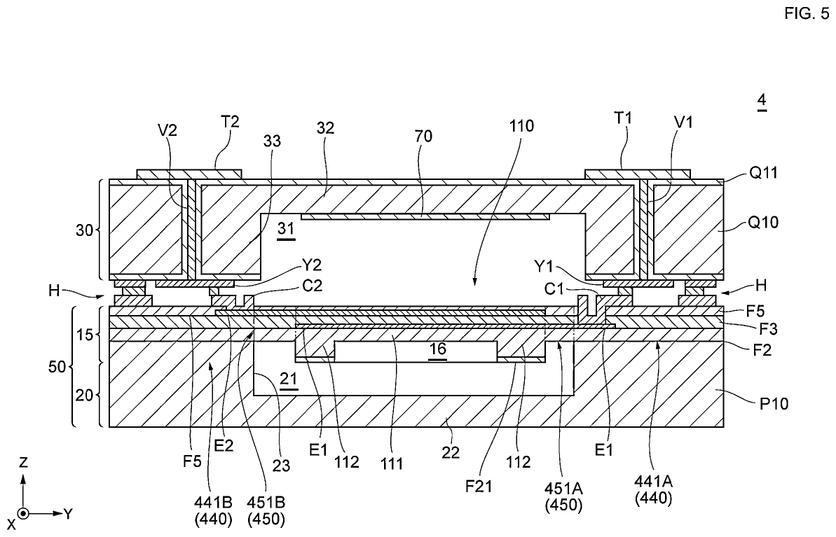

Next, a structure of a resonance device 4 according to a fourth embodiment will be described with reference to FIG. 5. FIG. 5 is a cross-sectional view schematically showing a structure of a resonator according to the fourth embodiment.

In the present embodiment, a thickness of a holding portion 440 is smaller than the thickness of the thick portion 112. In the example shown in FIG. 5, the thickness of the holding portion 440 is substantially the same as a thickness of a support portion 450 and is substantially the same as the thickness of the thin portion 111. A surface of a first support arm 451A on the lower cover 20 side and a surface of a first frame portion 441A on the lower cover 20 side are substantially flush with each other. Details thereof are the same for a second support portion 451B and a second frame portion 441B. In addition, in the example shown in FIG. 5, the silicon oxide film F21 is not provided on surfaces of the holding portion 440 and the support portion 450 on the lower cover 20 side, and the silicon substrate F2 is exposed. Alternatively, a silicon oxide film may be provided on the surfaces of the holding portion 440 and the support portion 450 on the lower cover 20 side.

As described above, since the thickness of the holding portion 440 is smaller than the thickness of the thick portion 112, a distance between the lower cover 20 and the upper cover 30 is shortened, and a thickness of the resonance device 4 is reduced. That is, the resonance device 4 can be reduced in size.

In addition, since the support portion 450 is formed to have the same thickness as the thin portion 111 and the holding portion 440, in a manufacturing process of the resonance device 4, etching processes of the support portion 450, the thin portion 111, and the holding portion 440 can be performed at one time, so that the manufacturing process can be simplified.

In a case where the thickness of the holding portion 440 is smaller than the thickness of the thick portion 112, the holding portion 440 may be formed to have a thickness different from the thickness of the thin portion 111 and the thickness of the support portion 450. For example, even in a case where the thicknesses of the thin portion 111, the holding portion 440, and the support portion 450 are different from each other, the thickness of the resonance device 4 can be reduced compared to a configuration in which the thickness of the holding portion 440 is substantially equal to the thickness of the thick portion 112. In addition, even in a case where the thicknesses of the holding portion 440 and the support portion 450 are substantially equal to each other and are different from the thickness of the thin portion 111, the etching processes of the holding portion 440 and the support portion 450 can be performed at one time. The same applies to a case where the thicknesses of the thin portion 111 and the holding portion 440 are substantially equal to each other and are different from the thickness of the support portion 450.

### Fifth Embodiment

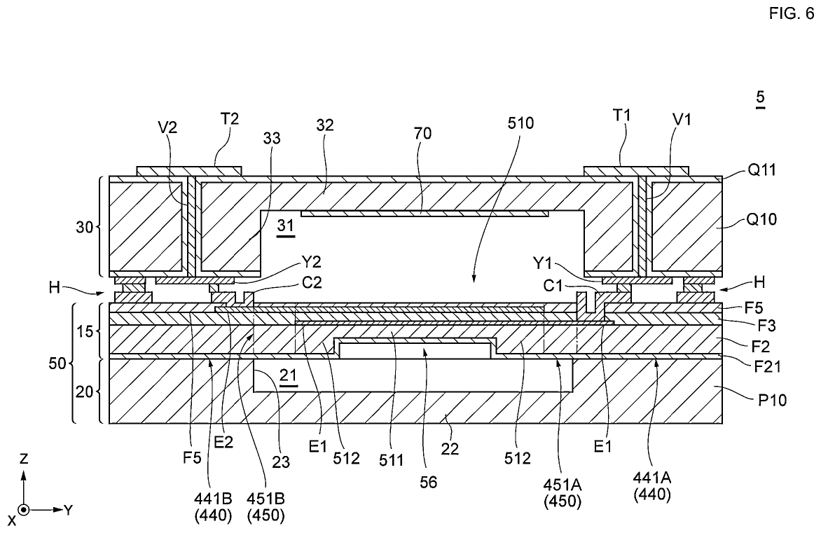

Next, a structure of a resonance device 5 according to a fifth embodiment will be described with reference to FIG. 6. FIG. 6 is a cross-sectional view schematically showing a structure of a resonator according to the fifth embodiment.

In the present embodiment, the silicon oxide film F21 is provided not only on a lower surface of a thick portion 512 of a vibrating portion 510 but also on a lower surface of a thin portion 511, that is, a bottom surface of a recess portion 56 of the vibrating portion 510. In other words, the silicon oxide film F21 is provided on a surface in a direction along the main surface of the silicon substrate F2 in the vibrating portion 510 on the lower cover 20 side of the silicon substrate F2. Accordingly, better frequency-temperature characteristics can be obtained. In addition, the silicon oxide film F21 may not be provided on a side surface of the recess portion 56. Therefore, the inhibition of vibration by the silicon oxide film is reduced compared to a configuration in which the silicon oxide film is continuously provided over the thick portion and the thin portion.

In the example shown in FIG. 6, the silicon oxide film F21 is provided on an entire surface of the lower surface of the thin portion 511, but the silicon oxide film F21 need only be provided on at least a part of the lower surface of the thin portion 511. In addition, the silicon oxide film F21 may be provided on a part of the side surface of the recess portion 56 as long as the silicon oxide film F21 is discontinuous at a boundary between the thick portion 512 and the thin portion 511.

### Sixth Embodiment

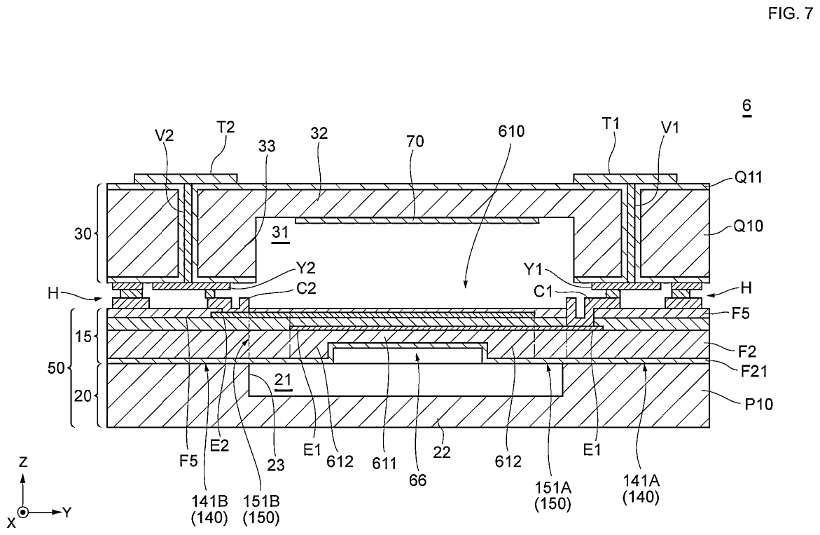

Next, a structure of a resonance device 6 according to a sixth embodiment will be described with reference to FIG. 7. FIG. 7 is a cross-sectional view schematically showing a structure of a resonator according to the sixth embodiment.

In the present embodiment, the silicon oxide film F21 is provided not only on a lower surface of a thick portion 612 of a vibrating portion 610 but also on a lower surface of a thin portion 611, and the silicon oxide film F21 is continuously provided over the thick portion 612 and the thin portion 611. In the present embodiment, unlike the fifth embodiment, the silicon oxide film F21 is also provided on a side surface of the recess portion 66 of the vibrating portion 610. In other words, the silicon oxide film F21 is provided on surfaces in a direction along the main surface of the silicon substrate F2 and in a direction intersecting the main surface in the vibrating portion 610 on the lower cover 20 side of the silicon substrate F2. That is, the silicon oxide film F21 is provided on an entire surface of the vibrating portion 610 on the lower cover 20 side. Therefore, in a manufacturing process, the silicon oxide film F21 can be formed after the formation of the recess portion 66, and a manufacturing cost can be lower than in the fifth embodiment.

### Seventh Embodiment

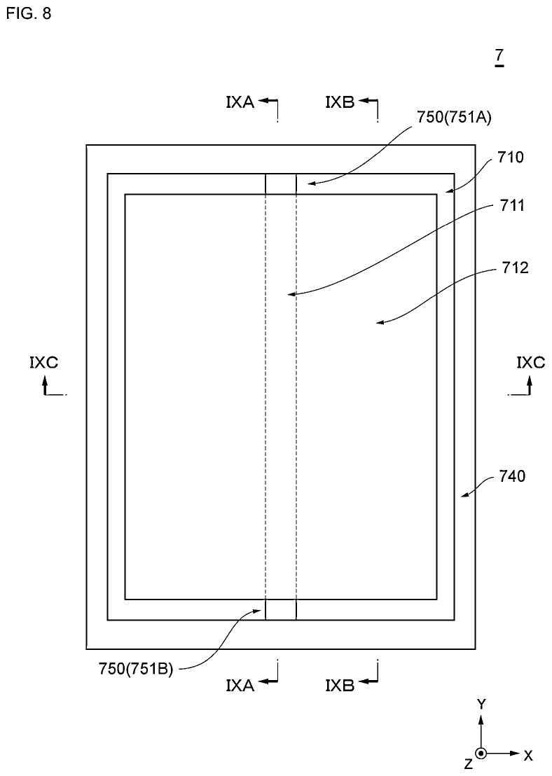

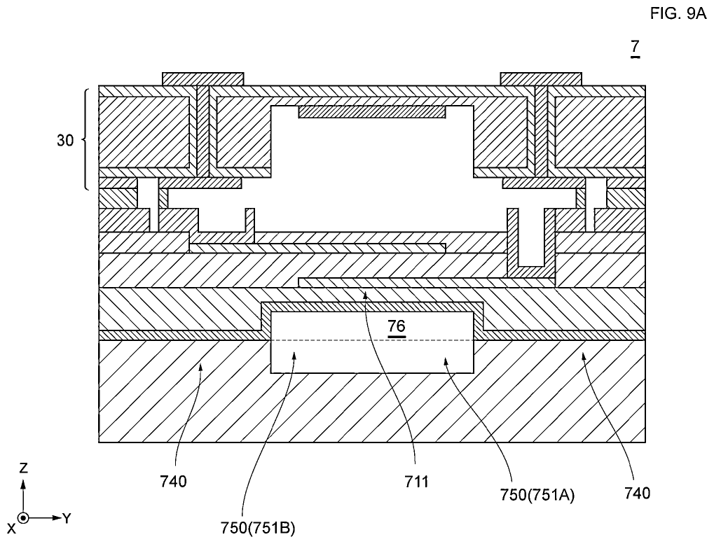

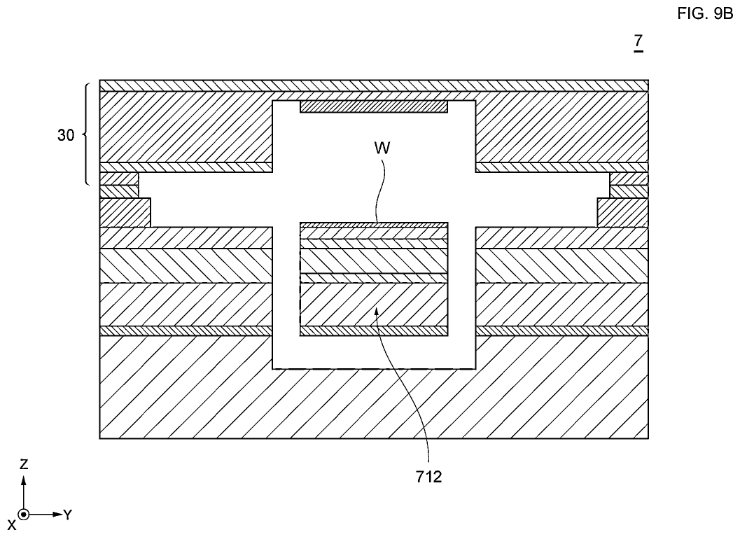

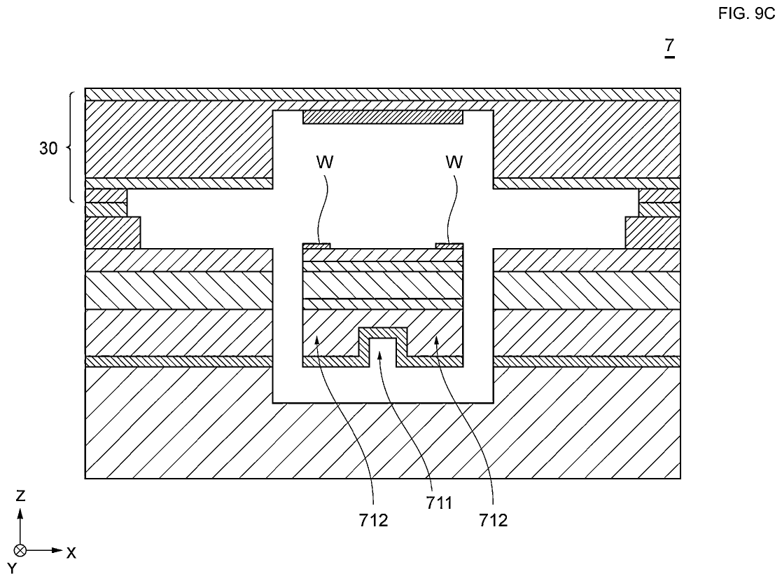

Next, a structure of a resonance device 7 according to a seventh embodiment will be described with reference to FIGS. 8 to 9C. FIG. 8 is a plan view schematically showing a structure of a resonator according to the seventh embodiment. FIGS. 9A, 9B, and 9C are cross-sectional views taken along lines IXA-IXA, IXB-IXB, and IXC-IXC of FIG. 8.

As shown in FIG. 8, a thin portion 711 extends, in a central region of a vibrating portion 710 sandwiched in the Y-axis direction between a first support arm 751A and a second support arm 751B of a support portion 750, in a band shape from the first support arm 751A to the second support arm 751B, and the first support arm 751A and the second support arm 751B are connected to the thin portion 711. A thick portion 712 is provided in an outer end region with the central region interposed between both directions of the X-axis. A width of the thin portion 711 in the X-axis direction is substantially equal to each of widths of the first support arm 751A and the second support arm 751B in the X-axis direction. That is, a recess portion 76 is provided in substantially the entire central region in which the displacement due to the vibration is smaller than that in the outer end region. Accordingly, compared to a configuration in which the recess portion is provided in a part of the central region in the Y-axis direction, the recess portion can be made larger while suppressing an influence on vibration characteristics, so that the vibration confinement property can be improved.

A thickness of the support portion 750 is, for example, smaller than thicknesses of the thick portion 712 and the holding portion 740. Since there is a change in thickness at a boundary between the support portion 750 and the holding portion 740, vibration leakage from the support portion 750 to the holding portion 740 can be suppressed. Therefore, the vibration confinement property can be improved. The thickness of the support portion 750 is, for example, substantially equal to a thickness of the thin portion 711, but is not limited thereto. The thickness of the support portion 750 may be larger than or smaller than the thickness of the thin portion 711.

In the example shown in FIG. 8, a planar shape of the thin portion 711 is a rectangular shape, but the planar shape of the thin portion 711 is not limited to the above-described shape as long as the thin portion 711 extends in a band shape from the first support arm 751A to the second support arm 751B. For example, the planar shape of the thin portion 711 may be a polygonal shape, a circular shape, an elliptical shape, or a combination thereof. In addition, the width of the thin portion 711 in the X-axis direction is formed to be substantially equal to the widths of the first support arm 751A and the second support arm 751B in the X-axis direction, but is not limited to this width. For example, in a region sandwiched between the first support arm 751A and the second support arm 751B in the Y-axis direction, the width of the thin portion 711 in the X-axis direction may be larger than or smaller than the widths of the first support arm 751A and the second support arm 751B in the X-axis direction.

A frequency adjusting film W is provided on an upper cover 30 side of the vibrating portion 710. The frequency adjusting film W is provided in the outer end region. Since a frequency of the vibrating portion 710 that vibrates with a wide band depends on a weight of the outer end region of the vibrating portion 710, the frequency can be adjusted by a trimming process of the frequency adjusting film W. From the viewpoint of suppressing the peeling or damage of the frequency adjusting film W caused by the strain during the vibration of the vibrating portion 710, it is preferable that the frequency adjusting film W is provided only in the outer end region, avoiding the central region where the strain during the vibration is large. From the viewpoint of accuracy of the trimming process, a width of the frequency adjusting film W in the X-axis direction is preferably 5 μm or more. Therefore, a width of the outer end region provided with the frequency adjusting film W in the X-axis direction is preferably 5 μm or more.

### Eighth Embodiment

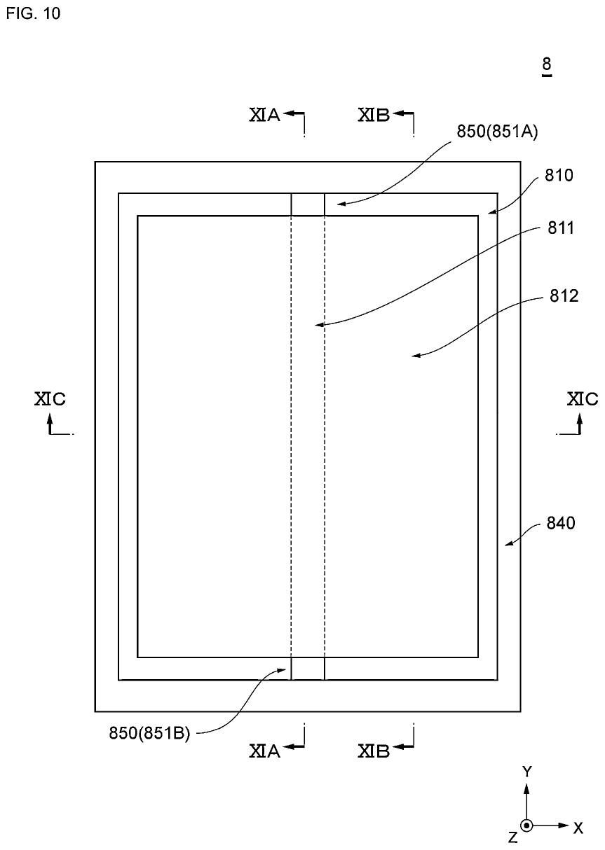

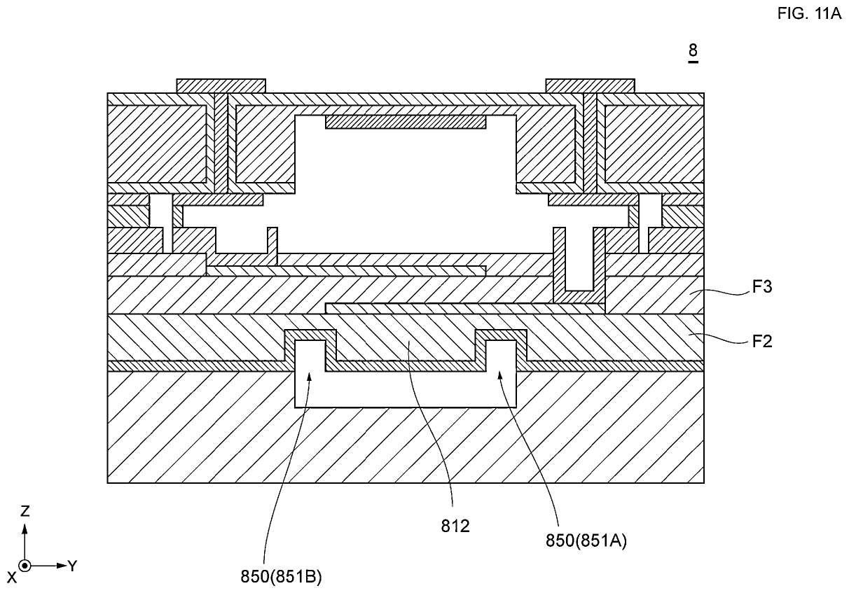

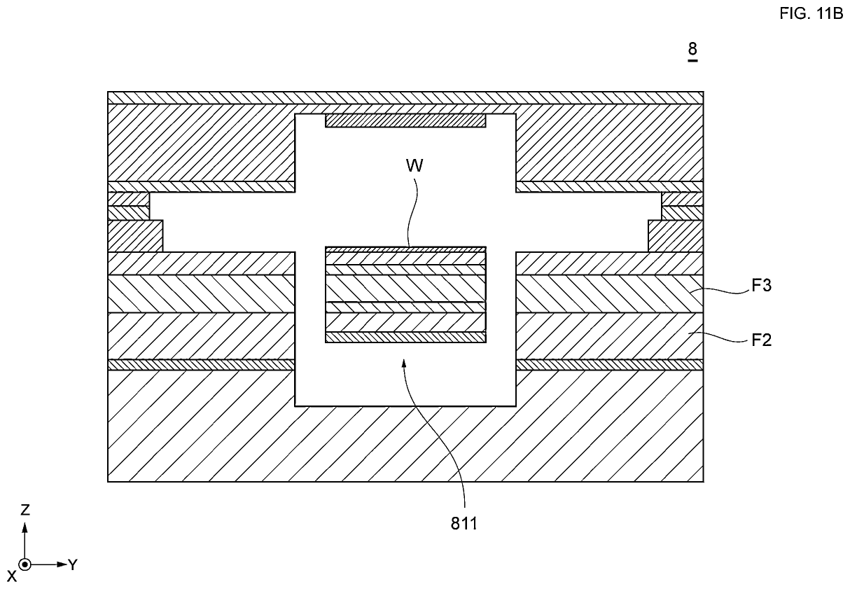

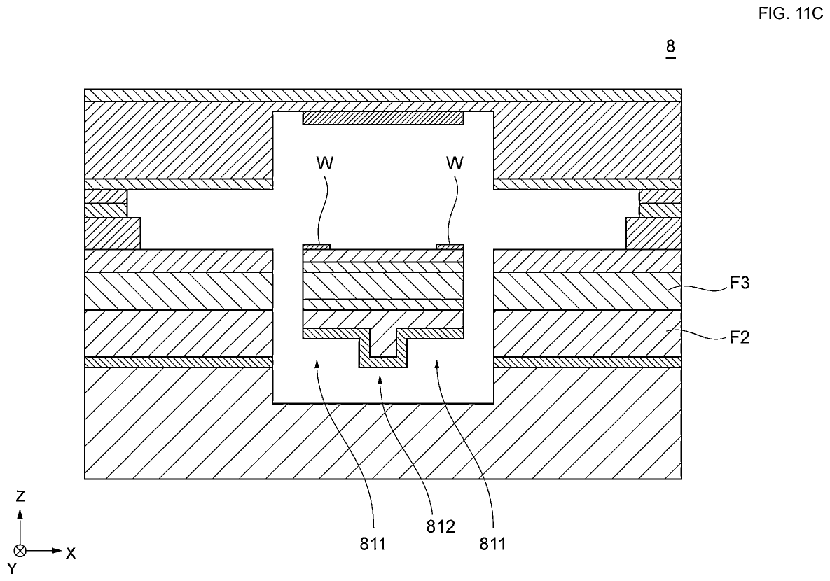

Next, a structure of a resonance device 8 according to an eighth embodiment will be described with reference to FIGS. 10 to 11C. FIG. 10 is a plan view schematically showing a structure of a resonator according to the eighth embodiment. FIGS. 11A, 11B, and 11C are cross-sectional views taken along lines XIA-XIA, XIB-XIB, and XIC-XIC of FIG. 10.

As shown in FIG. 10, in a vibrating portion 810, a thick portion 812 is provided in a central region sandwiched in the Y-axis direction between a first support arm 851A and a second support arm 851B of a support portion 850, the thick portion 812 extends in a band shape from the first support arm 851A to the second support arm 851B, and the first support arm 851A and the second support arm 851B are connected to the thick portion 812. A thin portion 811 is provided in an outer end region with the central region interposed between both directions of the X-axis. That is, the vibrating portion 810 is configured to have a protruding shape on a side opposite to the piezoelectric film F3 in the silicon substrate F2. Accordingly, a thickness of the central region in which an influence on the frequency-temperature characteristics in the vibrating portion 810 is large can be optimized. Therefore, even in a case where a desired frequency is obtained by reducing a thickness of the outer end region in which an influence on the frequency is large, favorable frequency-temperature characteristics can be obtained.

A thickness of the support portion 850 is, for example, larger than a thickness of the thin portion 811 and is substantially equal to thicknesses of the thick portion 812 and the holding portion 840. Since there is a change in thickness at a boundary between the vibrating portion 810 and the support portion 850, vibration leakage from the vibrating portion 810 to the support portion 850 can be suppressed. In addition, since there is a change in thickness at a boundary between the support portion 850 and the holding portion 840, vibration leakage from the support portion 850 to the holding portion 840 can be suppressed. Therefore, the vibration confinement property can be improved.

In the example shown in FIG. 10, a planar shape of the thick portion 812 is a rectangular shape, but the planar shape of the thick portion 812 is not limited to the above-described shape as long as the thick portion 812 extends in a band shape from the first support arm 851A to the second support arm 851B. For example, the planar shape of the thick portion 812 may be a polygonal shape, a circular shape, an elliptical shape, or a combination thereof. In addition, a width of the thick portion 812 in the X-axis direction is formed to be substantially equal to widths of the first support arm 851A and the second support arm 851B in the X-axis direction, but is not limited to this width. For example, in a region sandwiched between the first support arm 851A and the second support arm 851B in the Y-axis direction, the width of the thick portion 812 in the X-axis direction may be larger than or smaller than the widths of the first support arm 851A and the second support arm 851B in the X-axis direction.

Since a frequency of the vibrating portion 810 that vibrates with a wide band depends on a weight of the outer end region of the vibrating portion 810, the frequency can be adjusted by adjusting the thickness of the thin portion 811. The thickness of the thin portion 811 is adjusted, for example, by a trimming process of the silicon substrate F2 in the outer end region. Since a change in the thickness of the thick portion 812 in the central region causes a change in the frequency-temperature characteristics, it is preferable to perform the trimming process only on the outer end region while avoiding the central region. Therefore, from the viewpoint of accuracy of the trimming process, a width of the outer end region in the X-axis direction is preferably 5 um or more.

In the present embodiment, although the first support arm and the second support arm are connected to the thick portion, the thick portion may be provided in at least a part of the central region, and at least one of the first support arm or the second support arm may be connected to the thin portion. For example, the thick portion may be provided in a middle portion in the Y-axis direction (hereinafter, simply referred to as a “middle portion”) , and the thick portion may be provided in an island shape surrounded by the thin portion in a plan view. In such a configuration, the frequency-temperature characteristics can be adjusted by adjusting a ratio between the thick portion and the thin portion in the central region.

### Ninth Embodiment

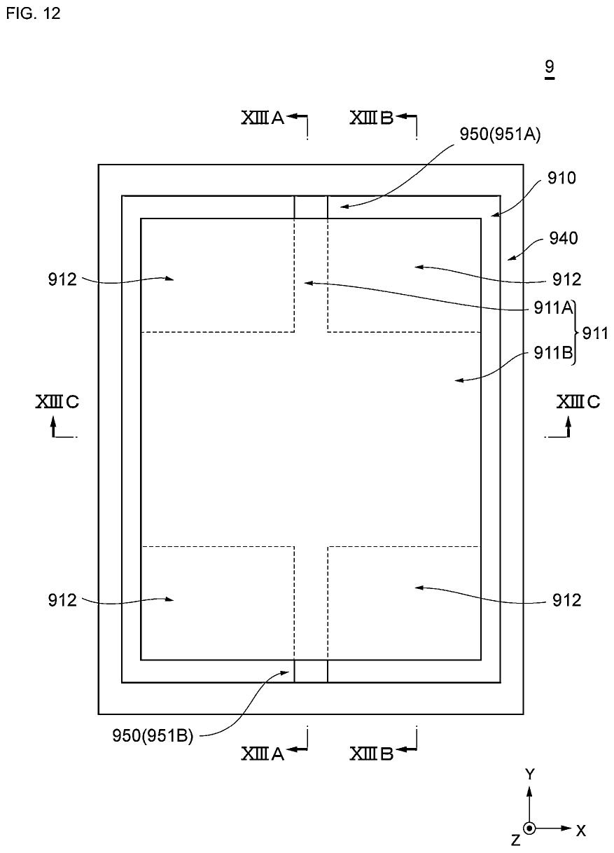

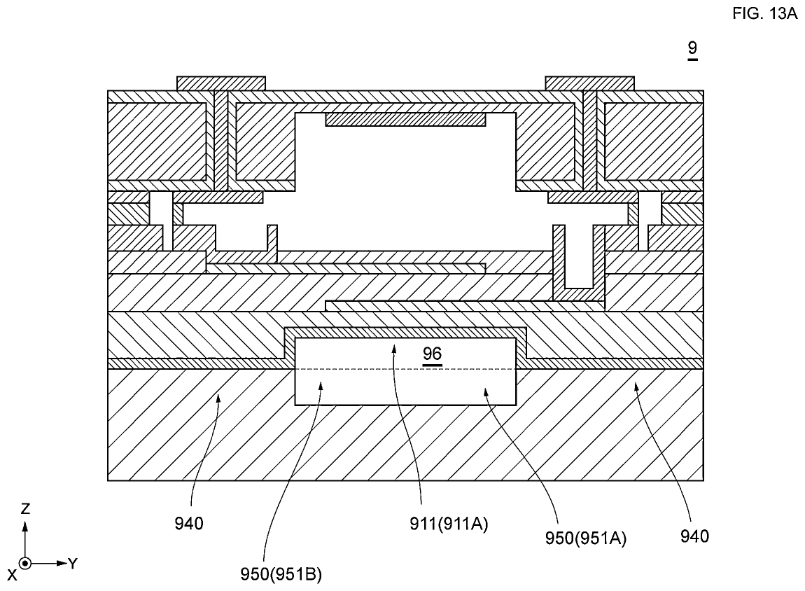

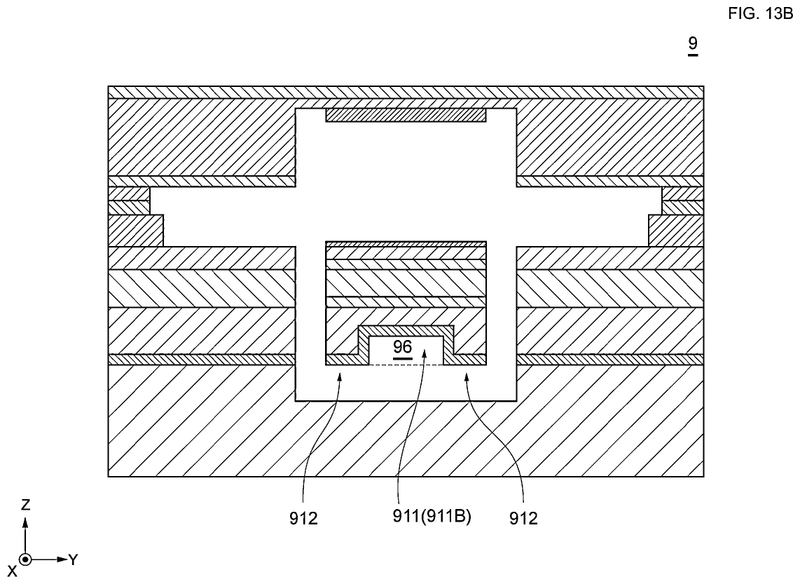

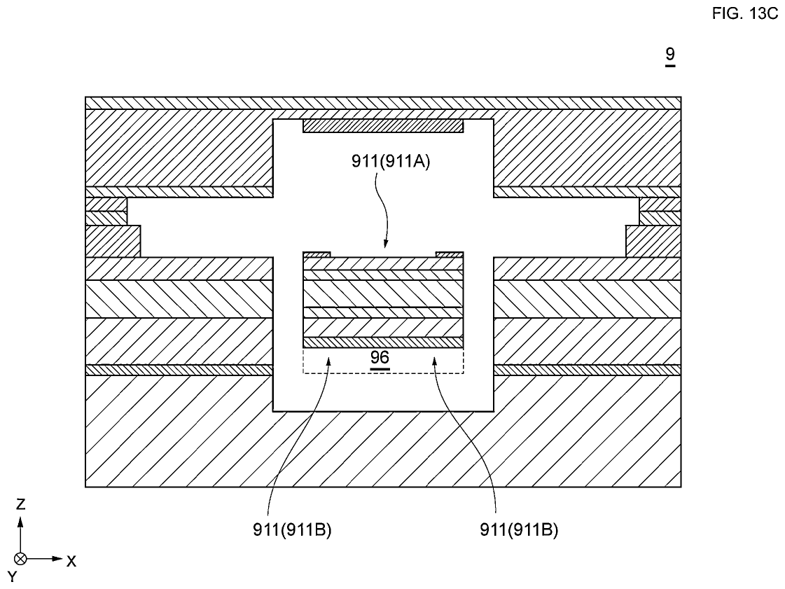

Next, a structure of a resonance device 9 according to a ninth embodiment will be described with reference to FIGS. 12 to 13C. FIG. 12 is a plan view schematically showing a structure of a resonator according to the ninth embodiment. FIGS. 13A, 13B, and 13C are cross-sectional views taken along lines XIIIA-XIIIA, XIIIB-XIIIB, and XIIIC-XIIIC of FIG. 12.

In the present embodiment, as in the seventh embodiment, in a vibrating portion 910, a thin portion 911 is provided in a central region sandwiched in the Y-axis direction by a first support arm 951A and a second support arm 951B of a support portion 950, and a thick portion 912 is provided in an outer end region with the central region interposed between both directions of the X-axis. However, in the present embodiment, unlike the seventh embodiment, the thin portion 911 is configured to have a wide width in a middle portion. That is, as shown in FIGS. 12 and 13C, the vibrating portion 910 includes a thin portion 911A provided in a middle portion of the central region, a thin portion 911B provided in a middle portion of the outer end region and adjacent to the central region, and thick portions 912 provided at four corners of the vibrating portion 910. Accordingly, it is possible to provide a resonance device having a higher vibration confinement property than that of the seventh embodiment.

In the example shown in FIG. 12, a planar shape of a middle portion of the thin portion 911 is a rectangular shape, but is not limited thereto. For example, the planar shape of the middle portion the thin portion 911 may be a polygonal shape, a circular shape, an elliptical shape, or a combination thereof. In the example shown in FIG. 13C, a thickness of the thin portion 911A is substantially equal to a thickness of the thin portion 911B, but may also be larger than or smaller than the thickness of the thin portion 911B.

In addition, in the example shown in FIG. 12, the thin portion 911B reaches an outer end of the vibrating portion 910 on each of both sides of the thin portion 911A in the X-axis direction. As a modification example, unlike the example shown in FIG. 12, the thin portion 911B does not reach the outer end of the vibrating portion 910 on both sides of the thin portion 911A in the X-axis direction, and may be provided at intervals from the outer end of the vibrating portion 910. In a case of this configuration, a middle portion outer end of the vibrating portion 910 may have the same thickness as the thick portion 912. In addition, in the case of this configuration, from the viewpoint of accuracy of a trimming process, a width of the thick portion 912 adjacent to the thin portion 911B in the X-axis direction is preferably 5 μm or more. In addition, it is preferable that the width of the thick portion 912 adjacent to the thin portion 911B in the Y-axis direction is also 5 μm or more.

In the present embodiment, the middle portion of the thin portion 911 is configured to have a wide width, but portions other than the middle portion may be configured to have a wide width. That is, the middle portion of the thin portion may be configured to have a narrow width.

### Tenth Embodiment

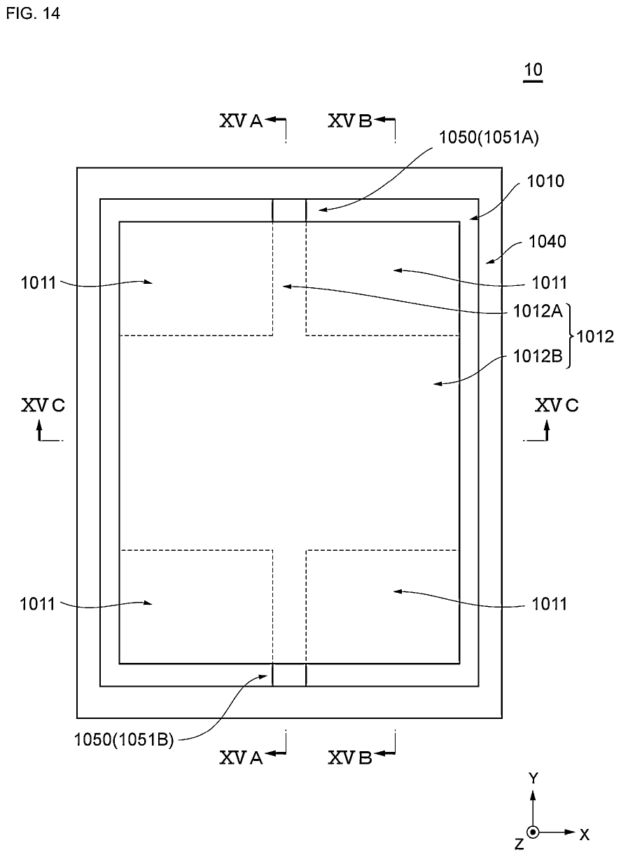

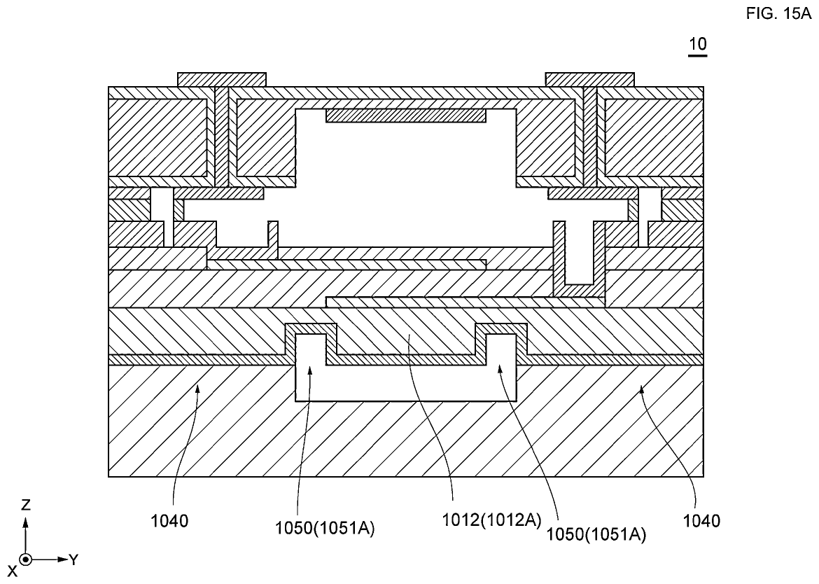

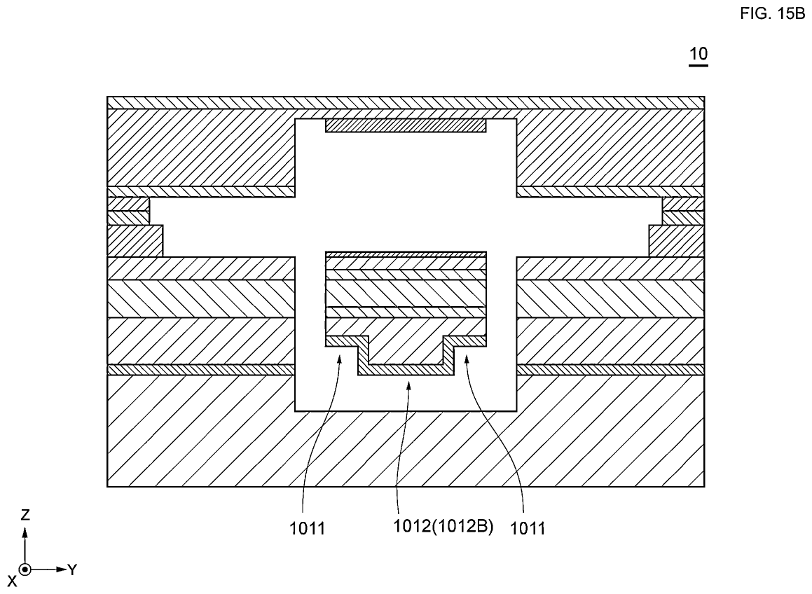

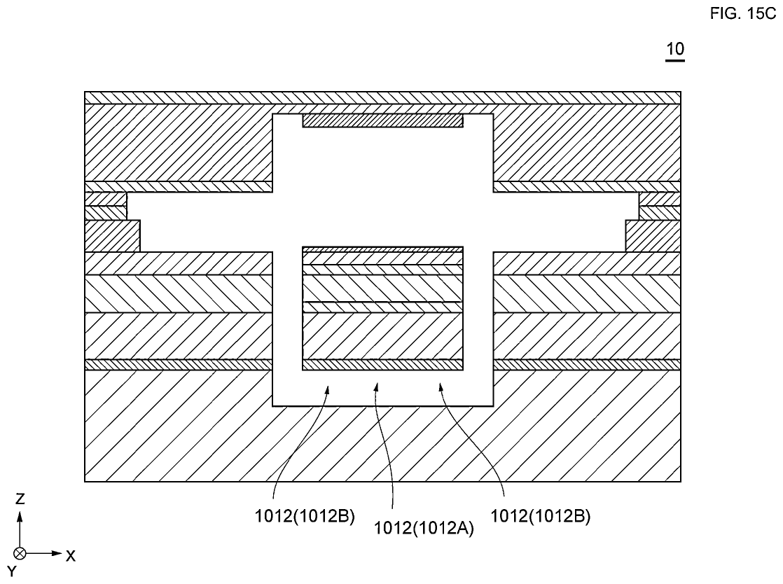

Next, a structure of a resonance device 10 according to a tenth embodiment will be described with reference to FIGS. 14 to 15C. FIG. 14 is a plan view schematically showing a structure of a resonator according to the tenth embodiment. FIGS. 15A, 15B, and 15C are cross-sectional views taken along lines XVA-XVA, XVB-XVB, and XVC-XVC of FIG. 14.

In the present embodiment, as in the eighth embodiment, in a vibrating portion 1010, a thick portion 1012 is provided in a central region sandwiched in the Y-axis direction between a first support arm 1051A and a second support arm 1051B of a support portion 1050, and a thin portion 1011 is provided in an outer end region with the central region interposed between both directions of the X-axis. However, in the present embodiment, unlike the eighth embodiment, the thick portion 1012 is configured to have a wide width in a middle portion. That is, as shown in FIGS. 14 and 15C, the vibrating portion 1010 includes a thick portion 1012A provided in a middle portion of the central region, a thick portion 1012B provided in a middle portion of the outer end region and adjacent to the central region, and thin portions 1011 provided at four corners of the vibrating portion 1010. Accordingly, it is possible to provide a resonance device having a higher vibration confinement property than that of the eighth embodiment.

In the example shown in FIG. 14, a planar shape of a middle portion of the thick portion 1012 is a rectangular shape, but is not limited thereto. For example, the planar shape of the middle portion of the thick portion 1012 may be a polygonal shape, a circular shape, an elliptical shape, or a combination thereof. In the example shown in FIG. 15C, a thickness of the thick portion 1012A is substantially equal to a thickness of the thick portion 1012B, but may be larger than or smaller than the thickness of the thick portion 1012B. In addition, a width of the thick portion 1012 in the X-axis direction is formed to be substantially equal to widths of the first support arm 1051A and the second support arm 1051B-in the X-axis direction, but is not limited to this width. For example, the width of the thick portion 1012-in the X-axis direction may be larger than or smaller than the widths of the first support arm 1051A-and the second support arm 1051B-in the X-axis direction.

In addition, in the example shown in FIG. 14, the thick portion 1012B reaches an outer end of the vibrating portion 1010 on each of both sides of the thick portion 1012A in the X-axis direction. As a modification example, unlike the example shown in FIG. 14, the thick portion 1012B does not reach the outer end of the vibrating portion 1010 on both sides of the thick portion 1012A in the X-axis direction, and may be provided at intervals from the outer end of the vibrating portion 1010. In a case of this configuration, a middle portion outer end of the vibrating portion 1010 may have the same thickness as the thin portion 1011. In addition, in the case of this configuration, from the viewpoint of accuracy of a trimming process, a width of the thin portion 1011 adjacent to the thick portion 1012B in the X-axis direction is preferably 5 μm or more. In addition, it is preferable that the width of the thin portion 1011 adjacent to the thick portion 1012B in the Y-axis direction is also 5 μm or more.

In the present embodiment, although the first support arm and the second support arm are connected to the thick portion, the thick portion may be provided in at least a part of the central region, and at least one of the first support arm or the second support arm may be connected to the thin portion. For example, the thick portion may be provided in the middle portion in the Y-axis direction, and the thick portion may be provided in an island shape surrounded by the thin portion in a plan view. In such a configuration, the frequency-temperature characteristics can be adjusted by adjusting a ratio between the thick portion and the thin portion in the central region.

In the present embodiment, the middle portion of the thick portion 1012 is configured to have a wide width, but portions other than the middle portion may be configured to have a wide width. That is, the middle portion of the thick portion may be configured to have a narrow width.

### Eleventh Embodiment

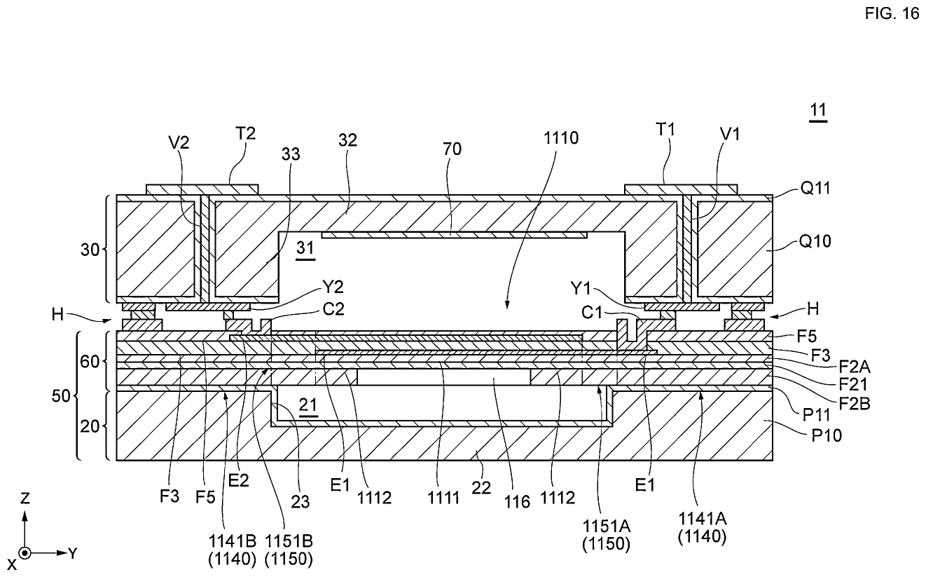

Next, a structure of a resonance device 11 according to an eleventh embodiment will be described with reference to FIG. 16. FIG. 16 is a cross-sectional view schematically showing a structure of a resonator according to the eleventh embodiment.

In the present embodiment, the resonator 60 includes a first silicon layer F2A and a second silicon layer F2B, and a silicon oxide film F21 is provided therebetween. The first silicon layer F2A is provided on an upper cover 30 side of the second silicon layer F2B. The first silicon layer F2A is provided over an entire region of a vibrating portion 1110, a holding portion 1140 (including a first frame portion 1141A and a second frame portion 1141B), and a support portion 1150 (that is, a first support arm 1151A and a second support arm 1151B). The first silicon layer F2A is provided with a uniform thickness in the thin portion 1111 and the thick portion 1112. The silicon oxide film F21 is similarly provided with a uniform thickness. The second silicon layer F2B is provided at the holding portion 1140 and the support portion 1150. The second silicon layer F2B is provided at the thick portion 1112 in the vibrating portion 1110, avoiding the thin portion 1111. Therefore, the silicon oxide film F21 is provided to be exposed to a bottom surface of a recess portion 116 in a thin portion 1111 of the vibrating portion 1110, and the second silicon layer F2B is provided to be exposed to a side surface of the recess portion 116. A thickness of the second silicon layer F2B may be larger than a thickness of the first silicon layer F2A. A silicon oxide film P11 is provided on a resonator 60 side of the lower cover 20. The silicon oxide film P11 is provided continuously over a joint surface between the silicon substrate P10 and the second silicon layer F2B and an inner surface of the cavity 21.

In an etching process of the recess portion 116 in a manufacturing process of the resonance device 11, a thickness of the thin portion 1111 can be adjusted with high accuracy by stopping etching at the silicon oxide film F21 provided between the first silicon layer F2A and the second silicon layer F2B, so that variations in frequency-temperature characteristics and in frequency can be suppressed.

The vibrating portion 1110 shown in FIG. 16 is an example of a vibrating portion in which a lower cover side is configured to have a recessed shape. However, the lower cover side of the vibrating portion may also be configured to have a protruding shape or a recessed shape other than the above as long as the resonator has the first silicon layer and the second silicon layer and the silicon oxide film is provided therebetween. For example, the vibrating portion may have a thick portion or a thin portion having a planar shape as in the seventh to tenth embodiments as long as the thick portion is constituted by the first silicon layer, the silicon oxide film, and the second silicon layer, and the thin portion is constituted by the first silicon layer and the silicon oxide film.

Hereinafter, a part or all of the embodiments of the present description will be appended below. The present description is not limited to the following addendum.

According to an aspect of the present description, there is provided a resonator including: a vibrating portion including a substrate, and a piezoelectric layer on a main surface of the substrate and which vibrates with a wide band along the main surface of the substrate in response to an applied voltage; a holding portion around at least a part of the vibrating portion in a plan view of the main surface of the substrate; and a support portion between the holding portion and the vibrating portion and that supports the vibrating portion, in which the vibrating portion includes a first portion in the plan view of the main surface of the substrate and a second portion in the plan view of the main surface of the substrate, a thickness of the second portion in a thickness direction intersecting the main surface of the substrate is larger than a thickness of the first portion in the thickness direction, and the vibrating portion has a recessed shape or a protruding shape defined by the first portion and the second portion on a side of the substrate opposite to the piezoelectric layer.

According to this aspect, by providing unevenness on the side in the substrate of the vibrating portion opposite to the piezoelectric layer, a vibration mode can be controlled, and unnecessary vibration such as bending vibration can be suppressed. Therefore, according to this aspect, it is possible to provide a resonator having a high vibration confinement property and a resonance device including the resonator.

As an aspect, the vibrating portion may be configured to have the recessed shape on the side in the substrate opposite to the piezoelectric layer, the first portion may correspond to a bottom portion of the recessed shape of the vibrating portion, and the second portion may correspond to a side wall portion of the recessed shape of the vibrating portion.

As an aspect, the support portion may be connected to the second portion, and a thickness of the support portion in the thickness direction may be equal to the thickness of the second portion in the thickness direction.

According to this aspect, the vibration mode can be controlled by the recess portion provided on the side in the substrate opposite to the piezoelectric layer, and the vibration confinement property of the resonator can be improved.

As an aspect, the support portion may be connected to the second portion, and a thickness of the support portion in the thickness direction may be smaller than the thickness of the second portion in the thickness direction.

According to this aspect, by the support portion having a small thickness, vibration leakage from the support portion can be suppressed, and further improvement in the vibration confinement property of the resonator can be achieved. In addition, by maintaining the thickness of the vibrating portion, favorable frequency-temperature characteristics can be obtained.

As an aspect, the thickness of the support portion in the thickness direction may be equal to the thickness of the first portion in the thickness direction.

According to this aspect, the support portion and the vibrating portion can be processed at one time, and a resonator having excellent productivity can be provided.

As an aspect, a thickness of the holding portion in the thickness direction may be equal to the thickness of the support portion in the thickness direction.

According to this aspect, a height of the holding portion can be reduced, so that a product height can be reduced and a size can be reduced.

As an aspect, the support portion may include a pair of support arms that are provided to face each other with the vibrating portion interposed therebetween, the first portion may extend in a band shape from one end to the other end of the pair of support arms in a region sandwiched by the pair of support arms in the vibrating portion, and the support portion may be connected to the first portion.

According to this aspect, by allowing the first portion and the second portion of the vibrating portion to have different thicknesses from each other, the vibration mode can be controlled, and the vibration confinement property can be further improved.

As an aspect, the first portion may be configured to have a middle portion that has a in a region extending in a band shape in the first portion.

According to this aspect, the vibration confinement property can be improved by the recess portion provided in the middle portion.

As an aspect, the vibrating portion may be configured to have the protruding shape on the side in the substrate opposite to the piezoelectric layer, and the second portion may correspond to a top portion of the protruding shape of the vibrating portion, and the first portion may correspond to a side wall portion of the protruding shape of the vibrating portion.

As an aspect, the support portion may include a pair of support arms that are provided to face each other with the vibrating portion interposed therebetween, and the second portion may extend in a band shape from one end to the other end of the pair of support arms in a region sandwiched by the pair of support arms in the vibrating portion, and the support portion may be connected to the second portion.

According to this aspect, favorable frequency-temperature characteristics can be obtained by optimizing a thickness of a vibrator middle portion sandwiched between the support arms.

As an aspect, the second portion may be configured to have a wide middle portion in a region extending in a band shape in the second portion.

According to this aspect, the vibration confinement property can be improved by the recess portion provided in the middle portion.

As an aspect, the vibrating portion may include a temperature characteristics correction film that corrects temperature characteristics of the substrate, and the temperature characteristics correction film may be provided on at least a part of the substrate on the side opposite to the piezoelectric layer.

As an aspect, the temperature characteristics correction film may be provided on a surface of the vibrating portion in a direction along the main surface of the substrate.

According to this aspect, by forming the temperature characteristics correction film in the vibrating portion, the temperature characteristics correction film is not formed on the surface of the piezoelectric layer, and thus the vibration is not inhibited. Therefore, favorable frequency-temperature characteristics can be obtained without impairing the vibration confinement property.

As an aspect, the temperature characteristics correction film may be further provided on a surface of the vibrating portion in a direction intersecting the main surface of the substrate.

According to this aspect, the temperature characteristics correction film can be formed at one time by thermal oxidation after film formation.

As an aspect, the substrate is a silicon substrate, and the temperature characteristics correction film is a silicon oxide film.

As an aspect, the substrate includes a first silicon substrate, a silicon oxide film provided on a side of the first silicon substrate opposite to the piezoelectric layer, and a second silicon substrate provided on a side of the silicon oxide film opposite to the piezoelectric layer, and the silicon oxide film is exposed on a side in the first portion opposite to the piezoelectric layer.

According to this aspect, thickness adjustment can be performed with high accuracy by stopping etching at a joint layer, so that variations in frequency-temperature characteristics and in frequency can be suppressed.

According to another aspect, there is provided a resonance device including: a resonator; a lower cover joined to a holding portion; and an upper cover joined to the holding portion to form an internal space in which a vibrating portion is accommodated between the upper cover and the lower cover.

The embodiments according to the present description can be appropriately applied without particular limitation to a device that utilizes frequency characteristics of a vibrator such as a timing device, a sound generator, an oscillator, and a load sensor.

As described above, according to the aspects of the present description, it is possible to provide a resonator and a resonance device capable of improving a vibration confinement property.

The embodiments described above are for facilitating the understanding of the present description, and are not intended to be construed as limiting the present description. The present description can be modified/improved without departing from the gist of the present description, and also includes equivalents thereof. That is, each embodiment with appropriate design changes by those skilled in the art is also included in the scope of the present description as long as the embodiment has the features of the present description. For example, each element and its arrangement, materials, conditions, shapes, sizes, and the like provided in each embodiment are not limited to the examples, and can be appropriately changed. In addition, the elements provided in the embodiments can be combined as technically possible, and a combination thereof is also included in the scope of the present description as long as the combination has the features of the present description.

### REFERENCE SIGNS LIST

1 resonance device
15 resonator
16 recess portion
20 lower cover
30 upper cover
50 mems substrate
110 vibrating portion
111 thin portion
112 thick portion
140 holding portion
150 support portion
F21 silicon oxide film
F2 silicon substrate
F3 piezoelectric film
E1, E2 metal film
F5 protective film 1

1. A resonator comprising:
a vibrating portion including a substrate, and a piezoelectric layer on a main surface of the substrate and which vibrates with a wide band along the main surface of the substrate in response to an applied voltage;
a holding portion around at least a part of the vibrating portion in a plan view of the main surface of the substrate; and
a support portion between the holding portion and the vibrating portion and that supports the vibrating portion,
wherein the vibrating portion includes a first portion in the plan view of the main surface of the substrate and a second portion in the plan view of the main surface of the substrate,
a thickness of the second portion in a thickness direction intersecting the main surface of the substrate is larger than a thickness of the first portion in the thickness direction, and
the vibrating portion has a recessed shape or a protruding shape defined by the first portion and the second portion on a side of the substrate opposite to the piezoelectric layer.

2. The resonator according to claim 1,
wherein the vibrating portion is configured to have the recessed shape on the side of the substrate opposite to the piezoelectric layer,
the first portion defines a bottom portion of the recessed shape of the vibrating portion, and
the second portion defines a side wall portion of the recessed shape of the vibrating portion.

3. The resonator according to claim 2,
wherein the support portion is connected to the second portion, and
a thickness of the support portion in the thickness direction is equal to the thickness of the second portion in the thickness direction.

4. The resonator according to claim 2,
wherein the support portion is connected to the second portion, and
a thickness of the support portion in the thickness direction is smaller than the thickness of the second portion in the thickness direction.

5. The resonator according to claim 4, wherein the thickness of the support portion in the thickness direction is equal to the thickness of the first portion in the thickness direction.

6. The resonator according to claim 5, wherein a thickness of the holding portion in the thickness direction is equal to the thickness of the support portion in the thickness direction.

7. The resonator according to claim 2,
wherein the support portion includes a pair of support arms that face each other with the vibrating portion interposed therebetween,
the first portion extends in a band shape from a first end to a second end of the pair of support arms in a region sandwiched by the pair of support arms in the vibrating portion, and
the support portion is connected to the first portion.

8. The resonator according to claim 7, wherein the first portion has a wider middle portion in a region extending in a band shape in the first portion.

9. The resonator according to claim 1,
wherein the vibrating portion has the protruding shape on the side of the substrate opposite to the piezoelectric layer, and
the second portion corresponds to a top portion of the protruding shape of the vibrating portion, and the first portion corresponds to a side wall portion of the protruding shape of the vibrating portion.

10. The resonator according to claim 2,
wherein the support portion includes a pair of support arms that face each other with the vibrating portion interposed therebetween,
the second portion extends in a band shape from a first end to a second end of the pair of support arms in a region sandwiched by the pair of support arms in the vibrating portion, and
the support portion is connected to the second portion.

11. The resonator according to claim 10, wherein the second portion has a wider middle portion in a region extending in a band shape in the second portion.

12. The resonator according to claim 1,
wherein the vibrating portion includes a temperature characteristics correction film constructed to correct temperature characteristics of the substrate, and
the temperature characteristics correction film is on at least a part of the substrate on the side thereof opposite to the piezoelectric layer.

13. The resonator according to claim 12, wherein the temperature characteristics correction film is on a surface of the vibrating portion in a direction along the main surface of the substrate.

14. The resonator according to claim 13, wherein the temperature characteristics correction film is further on a surface of the vibrating portion in a direction intersecting the main surface of the substrate.

15. The resonator according to claim 12,
wherein the substrate is a silicon substrate, and
the temperature characteristics correction film is a silicon oxide film.

16. The resonator according to claim 12, wherein
the vibrating portion is configured to have the recessed shape on the side of the substrate opposite to the piezoelectric layer,
the first portion defines a bottom portion of the recessed shape of the vibrating portion,
the second portion defines a side wall portion of the recessed shape of the vibrating portion, and
a depth of the recessed shape is larger than a thickness of the temperature characteristics correction film.

17. The resonator according to claim 2,
wherein the substrate includes a first silicon substrate, a silicon oxide film on a side of the first silicon substrate opposite to the piezoelectric layer, and a second silicon substrate on a side of the silicon oxide film opposite to the piezoelectric layer, and
the silicon oxide film is exposed on a side in the first portion opposite to the piezoelectric layer.

18. A resonance device comprising:
the resonator according to claim 1;
a lower cover joined to the holding portion; and
an upper cover joined to the holding portion to form an internal space in which the vibrating portion is accommodated between the upper cover and the lower cover.
